(19) United States
(12) Patent Application Publication
(10) Pub. No.: US 2016/0056767 A1
(43) Pub. Date: Feb. 25, 2016

(54) ENERGY-EFFICIENT MODE-SWITCH POWER AMPLIFIER SET

(71) Applicant: KABUSHIKI KAISHA TOSHIBA, Tokyo (JP)

(72) Inventors: Stephen WANG, Bristol (GB); Konstantinos MMIS, Bristol (GB); Justin COON, Bristol (GB)

(21) Appl. No.: 14/780,103

(22) PCT Filed: Mar. 28, 2013
(86) PCT No.: PCT/GB2013/050849

§ 371 Date: Sep. 25, 2015

(51) Int. Cl. H03F 1/02; H03F 3/21; H03F 3/19; H03F 3/217

(52) U.S. Cl. CPC H03F 1/0205; H03F 3/217; H03F 3/211; H03F 3/19; H03F 2200/451; H03F 2203/21109

(57) ABSTRACT

An amplifier device comprises two modes of operation. In a first mode, the amplifier device operates in a wideband mode, whereas in a second mode the amplifier operates in a narrowband mode. Switching in the amplifier device provides antenna selection, in either mode. Control of mode and antenna selection is carried out with reference to a probability based optimisation, as to whether changing mode and/or antenna selection will improve efficiency. By that, the energy consumption associated with switching can be accommodated in the optimisation, thereby offering an improvement to efficiency.

### FIELD

Embodiments described herein relate to power amplifiers.

### BACKGROUND

Computer based technologies are ubiquitous, and networking of computers is commonplace. The increase in use of computer based networking has given rise to increased concern about energy consumption.

### BRIEF DESCRIPTION OF DRAWINGS

FIG. 1 is a general outline of a system in accordance with a described embodiment.

FIG. 2 is a schematic diagram of a relay of the system illustrated in FIG. 1.

FIG. 3 is a schematic diagram of a radio driver of the relay illustrated in FIG. 2.

FIG. 4 is a schematic diagram of the radio driver of FIG. 3, in a first mode of operation.

FIG. 5 is a schematic diagram of the radio driver of FIG. 3, in a second mode of operation.

FIGS. 6 to 11 are graphs setting out simulation results for an example of the described embodiment.

### DESCRIPTION OF SPECIFIC EMBODIMENTS

A first embodiment provides a multi-mode power amplifier device comprising a signal input and first and second antenna outputs, each antenna output being suitable for connection to a corresponding antenna; a wideband power amplifier operable to amplify an input signal applied to an input thereof and to apply the amplified input signal to one of the antenna outputs; and a narrowband amplifier unit comprising a first narrowband amplifier and a second narrowband amplifier, wherein the first narrowband power amplifier is operable to amplify An input signal applied to an input thereof with respect to a first centre frequency and to apply the amplified input signal to the first antenna output; and the second narrowband power amplifier is operable to amplify an input signal applied to an input thereof with respect to a second centre frequency, different from the first centre frequency, and to apply the amplified input signal to the second antenna output; the amplifier device being operable in two modes, wherein in a first mode a signal applied at the signal input is presented to the wideband power amplifier for amplification thereof, and in a second mode a signal applied at the signal input is presented to the narrowband amplifier unit; the amplifier device being operable in two antenna selection states, wherein in the first mode, the antenna selection state determines the antenna output to which the amplified input signal is applied; and in the second mode, the antenna selection state determines to which of the first and second narrowband power amplifiers the signal applied at the signal input is applied and thus to which of the antenna outputs the amplified input signal is applied.

The amplifier device may further comprise a controller, the controller being operable to select one of the two modes and one of the two antenna selection states.

The controller may be operable to receive channel information concerning channels of communication associated with each of the wideband amplifier and the first and second narrowband amplifiers.

The controller may be operable to process the received channel information and to base its selection of modes and antenna selection states on that processed information.

The controller may be operable to determine a switching condition, the switching condition expressing a tendency for the mode and/or antenna selection state for transmission of a particular finite duration signal to be different from the mode and/or antenna selection state for a preceding finite duration signal amplified by the amplifier device, the switching condition being determined dependent on received channel information.

The switching condition may comprise an antenna selection state switching condition, the switching condition expressing a tendency for the antenna selection state, for a particular finite duration signal applied at the signal input, to be the same as for a preceding finite duration signal applied at the signal input, regardless of channel condition in the unutilised antenna selection state.

The switching condition may comprise a mode switching condition, the mode switching condition governing, on the basis of received channel information, whether the mode of the amplifier device for a particular finite duration signal applied at the signal input should be the same as for a preceding finite duration signal applied at the signal input, regardless of channel condition in the other mode.

A second embodiment comprises a controller for controlling a multi-mode amplifier device, the multi-mode amplifier device being operable in one of two modes selectable by a mode control signal provided by the controller, the two modes being a wideband mode and a narrowband mode, and in one of two output selection states, each output selection state being associated with a respective one of two outputs, the output selection state being selectable by an output selection state control signal, the controller being operable to determine a mode control signal and an output selection state for a finite operating period on the basis of preceding states of said signals for a preceding operating period and on the basis of conditions of channels defined by combinations of output and mode, such that a decision to change from at least one of the preceding states is based on an optimisation of efficiency of the wideband mode of the amplifier device as opposed to efficiency, turn-on delay and energy consumption associated with the narrowband mode of the amplifier device.

The controller may be operable to perform an optimisation to determine said decision, on the basis of a predetermined probability that switching mode will improve efficiency of said amplifier device.

The controller may be operable to perform an optimisation to determine said decision, on the basis of a predetermined probability that, in the event that said mode is said narrowband mode, switching output state will improve efficiency of said amplifier device.

A third embodiment comprises an amplifier device with two modes of operation. In a first mode, the amplifier device operates in a wideband mode, whereas in a second mode the amplifier operates in a narrowband mode. Switching in the amplifier device provides antenna selection, in either mode. Control of mode and antenna selection is carried out with reference to a probability based optimisation, as to whether changing mode and/or antenna selection will improve efficiency. By that, the energy consumption associated with switching can be accommodated in the optimisation, thereby offering an improvement to efficiency.

The use of computer based technology has increased significantly in recent years. Amongst the many developments in the field, computer networking is most notable, particularly the implementation of the internet. The class of technologies that this encompasses can be generally described as information and communication technology (ICT). Many technologies have combined to enable the provision of wireless internet services, such as on portable or hand held devices, for example laptops, smart phones and tablets, or more application specific devices such as medical monitors, bespoke enterprise specific devices (for example for couriers or delivery drivers) or home entertainment devices and domestic appliances.

The effect of this has been a significant increase in power consumption attributable to the use of ICT, with a consequent demand for electrical energy. It has been reported that over 3% of the worldwide electrical energy consumption is a direct consequence of the implementation and use of wireless networks and the Internet.

This electrical energy inevitably has a consequence in the emission of greenhouse gas, and other environmental impact. It is also apparent that the cost of electricity generation is dependent on the abundance and availability of convertible energy, such as from fossil fuels. This abundance and availability cannot be guaranteed. This is having an impact on the price of electricity. This impact will be felt by consumers in two ways, first in terms of the cost of electricity supply, and second in terms of the cost of equipment and internet service provision.

The demand for ubiquitous communication and broadband services appears to be ever increasing. It is thus reasonable to suppose that the above referenced percentage will increase much further in the near future. This will place a demand pressure on electricity supply, which will have ever more impact on price and environmental issues. As a result, there is interest in the energy efficiency of ICT services, both from an economic and an environmental perspective.

In addition, demographic trends point to an aging population, particularly in the parts of the world in which there is a market for consumer electronics goods. Improvements in healthcare, welfare and social structures have led to increased longevity. A greater proportion of people avoid death from sudden causes or acute illness before reaching old age. This increasing proportion of the population who reach old age presents healthcare providers with particular challenges, relating to the monitoring of chronic conditions, fitness and general well-being. Many elderly people are not specifically unwell, and so do not need constant medical care. However, such people may benefit from monitoring on a passive basis. This could have a preventative effect, in that chronic conditions could be detected earlier in their development, or could be managed more effectively. A slow decline in fitness can be difficult to detect, both by the subject and by the health professional. Without constant monitoring, trends in observable criteria may be difficult to determine.

Consequently, wireless body area networks (WBAN) have been proposed, particularly for use in personal health care. A WBAN may comprise a plurality of body sensor units (BSUs) and a central unit (BCU). Each BSU is placed on, in, or adjacent the body (dependent on the type and purpose of the BSU in question) in order to monitor one or more physiological quantities. The BCU will be able to communicate with available communication nodes external of the WBAN, to enable monitor data to be passed to a healthcare provider or the like, or to enable signalling data to be passed to the WBAN, such as to configure a particular monitoring schedule.

Presently, sensors can enable the monitoring of many different physiological quantities in this way. Examples may include breathing rate, heart rate, blood pressure, blood oxygenation levels, although this is a non-exhaustive list and the reader will appreciate that the present disclosure is not in any way limited to such examples. While the concept of a WBAN is at an early stage, the idea of providing small monitoring units, which can be placed about the person, is well-established. For instance, personal heart rate monitors are marketed for use during periods of exercise. Incorporating a facility within such a monitor to enable the monitor to establish wireless communication with another, closely adjacent device acting as a BCU, will not be inconceivable to the reader.

Use of a WBAN can give open up several opportunities. First, using a WBAN can reduce the reliance on wired communication between monitors and a control unit, which reduces wired connections about the person of a monitored subject, or between the monitored subject and an external signal processor. Both of these can contribute to greater freedom for the monitored subject. Second, using a WBAN can reduce reliance on human intervention, in that monitors can be placed about the person of the monitored subject, and left to perform a monitoring function without supervision. This can reduce the need for a care assistant, nurse or medical practitioner to be physically present to oversee the monitoring of vital signs. By this, such personnel can be allowed to carry out other tasks, in the knowledge that a WBAN can be used to monitor vital signs in their absence, and to send, electronically, a warning message should monitored quantities indicate an anomaly worthy of attendance. This can reduce reliance on in-patient care, and can further provide greater freedom of movement and independence to a monitored subject.

However, the establishment of reliable communication within, and to/from, a WBAN can present a significant challenge. This is because the component parts of the WBAN (that is, the BSUs and BCU) may be in near-constant relative movement, and the network as a whole may be in movement relative to communication hub nodes with which the BCU is configured to communicate. It is desirable to ensure that the various devices of the WBAN are sufficiently small and light so as not to unduly encumber the monitored person, and this will inevitably constrain the likely capability of a WBAN enabled device to establish strong and robust emission and detection of electromagnetic signals, both in terms of the maximum power output of such a device and the energy storage capability of a battery incorporated in such a device.

Relay networks have been considered as an effective method to provide reliable communication, by exploiting transmission diversity. In particular, such a diversity can be achieved by jointly selecting the best relay node and antenna in either amplify-and-forward systems or decode-and-forward systems. Although outage probability, throughput and delay are key parameters to be optimized in relay networks, energy efficiency in such networks is also a critical factor.

This is especially relevant in scenarios where battery-powered devices are considered. It would be highly inconvenient to a person on whom a WBAN is installed, for a need to be imposed for regular and frequent re-charging of batteries to support various monitoring devices. Should a patient be fitted with several personal monitors, the re-charging problem will be compounded. Should a device in a WBAN discharge, this could have a considerable impact on the reliability of observations collected by the device, and by the WBAN as a whole. Since one possible motivation for implementing a WBAN is that it could be in lieu of the direct attention of a healthcare professional, failure of a WBAN could be significant, both in terms of the welfare of the patient and in terms of the liability of the healthcare provider.

Furthermore, energy-efficient relaying in WBAN for health care has also attracted attention due to its efficient bandwidth utilization with full transmission diversity. Examples of this include an arrangement whereby wireless devices transmit data from the subject to a local relay node. The data can then be forwarded from the local relay node in real-time to a hospital via heterogeneous radio access technologies (RAT), such as using cellular systems or WiFi. Heterogeneous RATs usually operate in diverse frequency channels and offer great mobility and flexibility, but also enhance the energy efficiency of the system.

Taking the IEEE 802.15.6 as an example, a wide range of frequency channels, namely, from 402 MHz-405 MHz (implant channels) to 2.4 GHz and 3.1-10.6 GHz (on-body channels), have been investigated to facilitate the standardization of WBAN and health care applications. Switching and operating between these channels can improve the transmission reliability and diversity. However, it is challenging to design hardware which is operable in different frequency channels which may be spaced considerably in frequency, particularly when switching between channels is taken into account. The transmission reliability and diversity, enabled by using channels spaced in frequency, may come at the cost of low energy-efficiency, if the PA modules are not carefully designed.

A trade-off exists between transmission diversity and energy consumption. Specifically, it is known that a wideband power amplifier (PA) in the RF chain usually has a lower efficiency than a narrowband PA. Therefore, a wideband PA is generally less energy-efficient and environmentally friendly. On the other hand, switching between narrowband PAs for heterogeneous access leads to higher energy consumption and delay. Therefore, the design of energy-efficient PA modules in real-time heterogeneous RATs with switching is a practical issue that must be addressed.

Embodiments disclosed herein provide a mode-switch PA set for a relay node in a heterogeneous RATs-compatible body area environment. Embodiments provide an optimal PA and antenna selection mechanism to optimize the energy efficiency, while, at the same time, satisfying two constraints on outage probability and transmission delay.

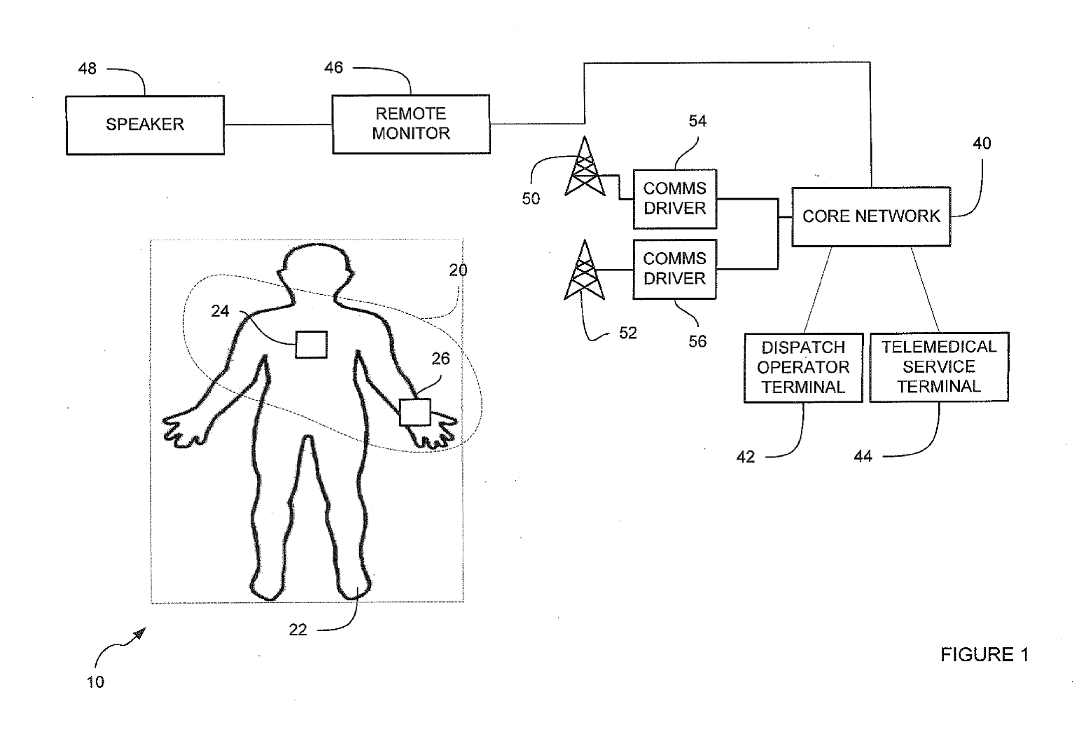

FIG. 1 illustrates a communications system 10 incorporating a WBAN 20. The WBAN is implemented on the person of a human patient 22. The WBAN comprises a heart monitor 24 and a relay 26. The heart monitor 24, as illustrated, has a single antenna, while the relay 26 has two antennas.

The reader might consider the heart monitor as a BSU and the relay 26 as a BCU as discussed above. However, the present disclosure should be considered without reference to any preconceived notion as to the function of a BSU or BCU, and any externally established definition of such terms should not impose any implied limitation on the functionality of the heart monitor 24 and the relay 26. For this reason, the terms BSU and BCU are not used with reference to the embodiment illustrated in FIG. 1.

Equally, while the embodiment is shown as being implemented in a WBAN environment, it is noted that the term WBAN should not be considered to limit the scope of the present disclosure to a particular standardised technology which may arise through adoption of a technical specification either by an international standardisation authority or by a private sector standardisation arrangement. The term WBAN should be viewed as a purely descriptive term, for a wireless communications environment suitable for use in establishing a network of cooperating wearable computing devices.

The WBAN 20 in FIG. 1 is capable of connection to a core network 40. The core network 40 comprises a communications network, which can be implemented using wired and/or wireless communications. Generally, such a core network could involve a mixture of communications technologies. The core network 40 offers communication to a plurality computer implemented nodes. As illustrated, a first computer implemented node comprises an dispatch operator terminal 42, for use by a dispatch operator. A dispatch operator is an operative assigned the task of dispatching fast response vehicles to an acute medical situation. The reader will appreciate that dispatching of fast response vehicles may be carried out by such a dispatch operator, or may involve other levels of computerised automation which are beyond the scope of this disclosure.

Another computer implemented node comprises a telemedical service terminal 44. The telemedical service terminal 44 is for use by a medical practitioner (e.g. a nurse or a doctor), to enable the provision of a telemedical service to the subject. To enable this, a remote monitor 46 is provided, in communication with the core network 40, which can be installed in the residence of the subject. A suitable product would be the IK-WB16A network camera produced by Toshiba Corporation. This product comprises a digital camera on a motorised mount, enabling remote tilting and re-orientation of the camera by a remote operator (such as at the telemedical service terminal 44). The product also has an integrated microphone, and an audio output. Other products would also be appropriate, including products with fewer integrated facilities. A speaker 48 is connected to the remote monitor, by which an audio output can be generated, such as for the emission of spoken messages from the medical practitioner. By this arrangement, a medical practitioner would be able to examine the subject remotely, and to receive and send audio messages to enable treatment of an acute medical situation to commence.

The core network 40 is provided with two antennas 50, 52. Each antenna 50, 52 has an associated communications driver 54, 56 implementing its respective radio access technology (RAT1, RAT2). The relay 26 is capable of connection, via the respective radio access technology, to one of the antennas, depending on signal conditions. The relay 26 is used to establish connection between the WBAN 20 and the core network, via one of the antenna driver combinations (50, 54; 52, 56).

In the WBAN 20, the heart monitor 24 collects a packet of body index data, the relay 26 receives and forwards this packet via one of the antennas 50, 52 to the core network, and thence to one of the terminals 42, 44. The destination terminal 42, 44 then processes the packet and delivers the appropriate health care responses.

For the purpose of this disclosure, it is assumed that the antennas of the relay 26 transmit equal power P₀, and that all links in the network exhibit independent and identically distributed Rayleigh fading.

For the purpose of this example, a data packet consists of K transmission blocks. It can be assumed that the channel remains invariant over the period of a block k, k∈{1, 2, . . . , K}, and is independent between blocks. Moreover, it can be assumed that the relay 26 has perfect knowledge of the channels. The present embodiment makes use of a half-duplex communication system.

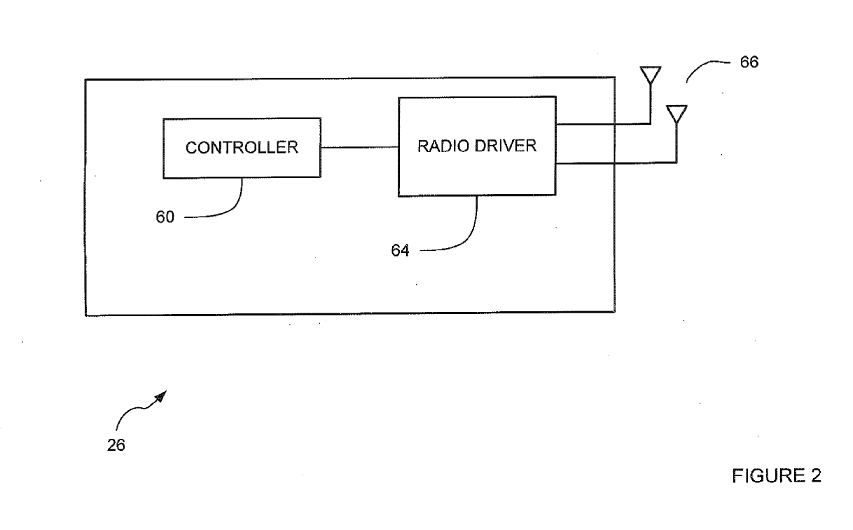

For illustration purposes, and as mentioned above, the present example provides two relay antennas, i.e., L=2. However, the reader will appreciate that the present disclosure can also be applied to cases with more than two relay antennas (i.e. L>2). The relay 26 is illustrated in further detail in FIG. 2.

As shown in FIG. 2, the relay 26 comprises a controller 60 and a radio driver 64. The two aforementioned antennas 66 are also illustrated. The controller 60 is operable to emit control signals to the radio driver 64. The controller 60 is also capable of monitoring the channels available for use by the relay 26, to gather channel information.

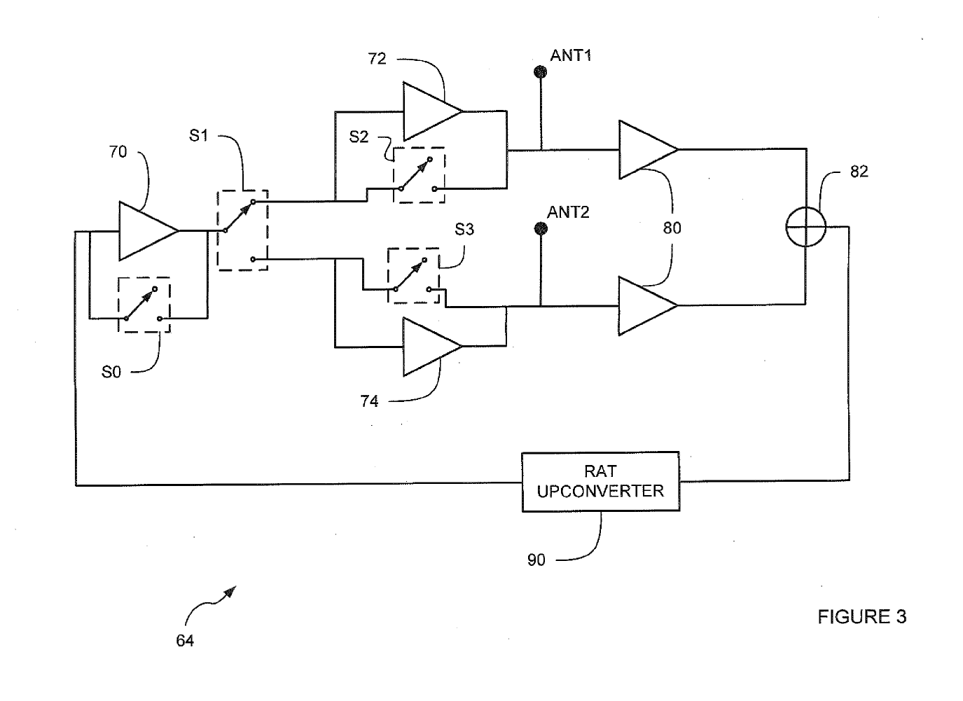

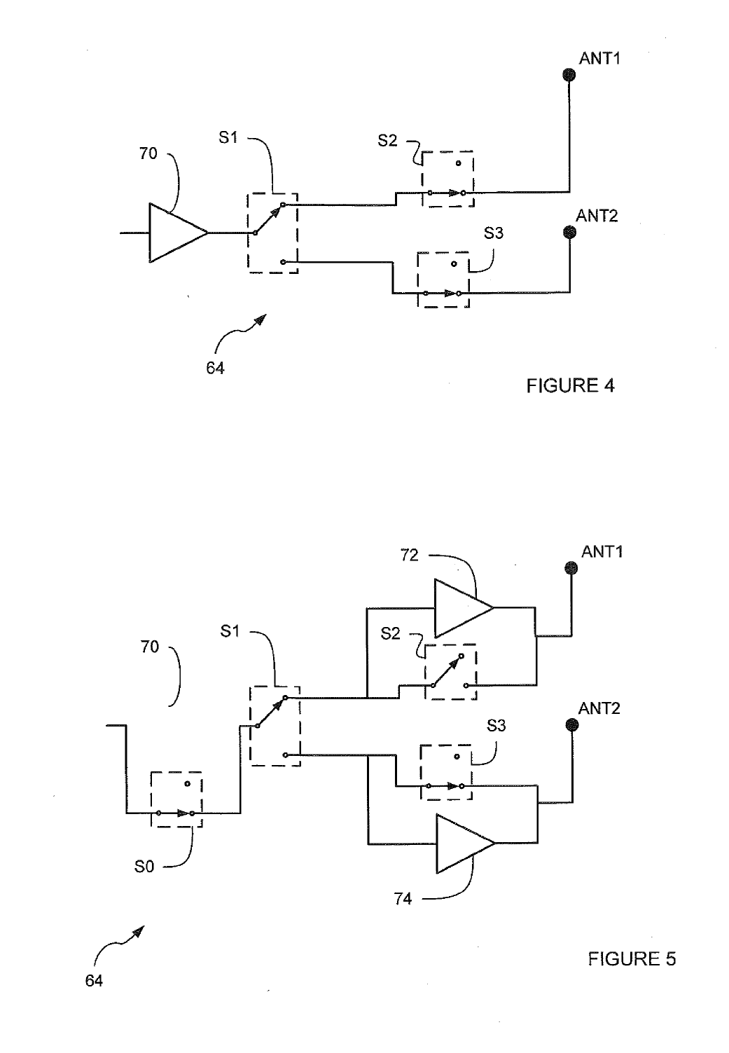

The radio driver 64 is illustrated in further detail in FIG. 3. For illustrative purposes, the radio driver 64 is further illustrated in FIGS. 4 and 5 in respective operating modes, namely Mode A and Mode B.

The radio driver 64 comprises a wideband power amplifier 70 which is operable to amplify signals in a wideband frequency range. For the purpose of this example, the wideband frequency range is 2.4 GHz to 3.5 GHz, but this range is not prescriptive.

A single pole, single throw switch S0 bridges the input and output of the wideband power amplifier 70 so that, when S0 is closed, the wideband power amplifier is bypassed.

The output of the wideband power amplifier 70 passes to a common contact of a single pole, double throw switch S1. The two switched contacts of switch S1 each pass to an input of respective narrowband power amplifiers 72, 74.

The narrowband amplifiers 72, 74 are tuned to distinct radio frequencies. In this example, the narrowband amplifier 72 associated with antenna ANT1 is tuned to 2.4 GHz, while the narrowband amplifier 74 associated with antenna ANT2 is tuned to 3.5 GHz. The reader will appreciate that other frequencies could be selected.

The outputs of the two narrowband power amplifiers 72, 74 pass to respective antennas 66 (ANT1, ANT2). Bridging across each narrowband power amplifier, from input to output, are respective single pole single throw switches S2, S3. As before, when S2 or S3 are closed, their respective narrowband power amplifier is bypassed.

This describes the components forming the transmission channel of the radio driver 64. In the case of detection of signals at the antennas, two LNAs 80 are provided, one per antenna 66. Each LNA 80 is connected to an antenna (ANT1, ANT2) and is operable to amplify a signal detected at the antenna. The LNAs of this example are both tuned to 2.4GHz, it being a feature of this example that all signals in the down channel are centred at that frequency. Detected, amplified signals are combined at a signal combiner 82 before being passed to an RAT upconverter 90. The signal combiner 82 operates using a maximum likelihood combining approach, as will be understood by the reader. The RAT upconverter 90 is configured to upconvert a received signal, to be relayed again by the transmission side of the relay at the chosen RAT.

In use, therefore, the radio driver can be configured in two ways, each associated with a mode of operation, respectively Mode A and Mode B. As illustrated in FIGS. 4 and 5, only the transmission channel, i.e. the transmission of signals, is affected by mode selection—the operation of the receive channel is unaffected and so is omitted from illustration.

Mode selection is achieved by configuration of the switches S0, S1, S2, S3. In Mode A, switch S0 is open, rendering the wideband power amplifier 70 operational. Switch S1 can be used to direct the output of the wideband power amplifier 70 towards either antenna ANT1 or antenna ANT2. Switches S2 and S3 are closed, which switches out the use of the narrowband power amplifiers 72, 74. Thus, in Mode A, a signal received by the radio driver 64 will be amplified by the wideband power amplifier 70 and then emitted, selectively, at either antenna ANT1 or antenna ANT2, selection being achieved by switching switch S1.

In Mode B, switch S0 is closed and switches S2 and S3 are opened. This bypasses the wideband power amplifier 70 and interposes the narrowband power amplifiers 72, 74 in the respective paths to the antennas ANT1, ANT2. Consequently, the received signal is directed, by switch S1, to either of the narrowband power amplifiers 72, 74. The narrowband amplifier 72, 74 to be used is activated by opening the corresponding one of the bypass switches S2, S3, the other being closed. As illustrated, the first narrowband amplifier 72 is in use, by selection on switch S1 and activation at switch S2. Thus, a narrowband signal emanates from the radio driver, to a selected one of the antennas. Further, the frequency at which a narrowband signal is to be emitted can be chosen.

Thus, for transmission from the relay 26 to the core network (via either antenna driver combination 50, 54 or antenna driver combination 52, 56) there are two alternative communications modes, namely using a wideband PA or one of the narrowband PAs.

In Mode A, when the wideband PA 70 is used, antenna selection is performed for every transmission block. On the other hand, in Mode B, if the narrowband PAs 72, 74 are employed, antenna selection is performed with a probability of 1−Pₛ, where Pₛ is defined as the ‘stay probability’.

In other words, the relay selects and switches between antennas, to establish a link to one of the antennas 50, 52 associated with the core network, to exploit diversity while satisfying transmission constraints. The criterion for selecting the active link is given by selecting the maximum of channel gain amongst the various available channels, taking into account that, in this example, there are two antennas at the relay 26 and two RATs associated with the core network 40.

This can therefore be denoted as being a determination of the maximum channel gain between Rᵢ (where R denotes the relay 26 and i indicates antenna selection at the relay 26) and D (D denoting “destination node”, i.e. the selected antenna/driver combination at the core network and its associated RAT) in the k^{th} block among all L relay links. Heterogeneous RATs are employed in this system to improve transmission reliability.

The illustrated architecture requires a minimum of three PA modules. The target output power of the system of this example is set to 20 dBm. Such a system has four states or more and transmission can be achieved through either the wideband PA, which should be able to cover all bands, (as per FIG. 4) or one of the narrowband PAs, in either of the supported bands (as per FIG. 5). This enables the exploitation of transmission diversity and the optimization of the system to minimize the impact of the realistic turn-on characteristics of PAs (in terms of both delay and power consumption).

The example demonstrated supports two RATs. Such a PA set enables the relay node to work in a flexible and energy-efficient manner. In particular, four transmission states can be realized by employing the following two modes.

In Mode A (FIG. 4), the two narrowband PAs 72, 74 are powered off and bypassed by RF switches S2 and S3, and the wideband PA 70 operates with an antenna selection mechanism (effected by switch S1) that chooses the best antenna based on channel gain. In Mode B (FIG. 5), the wideband PA 70 is powered off and bypassed by switch S0 while switch S1 is used to select between the narrowband PAs 72, 74 and their corresponding antennas. Thus, to emphasise, in Mode A, the radio driver 64 only switches between antennas while, in Mode B, both antennas and PAs are switched.

It will be evident to the reader that Mode B appears more energy efficient than Mode A, in that it is narrowband rather than wideband. However, this is to overlook the effect of turn-on characteristics of power amplifiers. Since, in Mode B, the narrowband PAs 72, 74 will be switched on and off frequently in order to effect antenna selection, this can have an impact. This can be expressed as an excess delay τₙ, and additional energy consumption J_{τ}_{ₙ}. Thus, it is reasonable to consider how frequently antenna switching should occur, within Mode B, to optimize the energy efficiency while still exploiting the transmission diversity.

On the other hand, in Mode A, a wideband PA is used, which will be perceived as inherently low efficiency. However, in employing the wideband PA, there is no excess delay and energy consumption from antenna selection. It would therefore be reasonable to conclude that antenna selection can always achieve selection of the antenna with the higher channel gain, for each transmission block. It follows, from this, that it is possible to employ Mode A for the best overall energy efficiency if the excess delay and energy cost in Mode B cannot be tolerated.

By considering the transmission constraints imposed on each mode in turn, it is reasonable to further consider how to select between the modes, for the best energy efficiency.

To address these two considerations, two probabilities are used to facilitate the optimization of energy efficiency. As previously mentioned, Pₛ is the stay probability, expressing the probability in Mode B that transmission will stay in the current Rᵢ-D link for the next transmission block (block k+1) using the same antenna i and PA even if the channel gain of the other antenna, j, is higher. Further, Pₙ is the operation probability of Mode B, expressing the probability that Mode B is employed. So, if Pₙ=1, Mode B is always employed.

Using these two probabilities, a switch/stay mechanism is implemented through which energy efficiency can be managed. The switch/stay mechanism is implemented as a process executed by the control unit 60.

The design of the switch/stay mechanism to maximize the energy efficiency requires determining Pₛ and Pⁿ, which depend on the efficiency of the wideband PA 70, and the efficiency, turn-on delay, and extra energy consumption corresponding to use of the narrowband PAs 72, 74. Pₛ and Pₙ are also subject to other constraints, such as the target outage probability and transmission delay.

In the following description, Pₒᵤₜ is the outage probability in the S-R-D (Source Relay Destination) transmission, and τ is the transmission delay. Thus, the optimization problem for any given turn-on delay can be expressed as:

maxη(Pₛ,Pₙ,τₙ)

subject to

τ(Pₛ,Pₙ,τₙ)≦D

Pₒₙᵢ(Pₛ,Pₙ)≦P

where η is the relay node's energy efficiency, and D, P are the thresholds for the delay of the data transmission, and the outage probability, respectively. The energy efficiency η of the relay node for one data packet transmission is given by:

$$η = \frac{1}{K} {\sum }_{k = 1}^{K} {η}_{k} ,$$

where ηₖ is the energy efficiency in the k^{th} block:

$$η ( {P}_{s} , {P}_{n} , {τ}_{n} ) = T \frac{{B}_{k}}{{J}_{k} + {J}_{c}}$$

where

T is the duration of one block,

Bₖ is the data rate of the k^{th} block using the PA set

Jₖ is the corresponding energy consumption in Joules and

J_{c} is the fixed energy (again, in Joules) consumed in all other parts of the circuitry excluding the energy consumption of the PA.

Upper and lower bounds of Pₛ can be derived for any given Pₙ. The upper bound is determined by letting Pₒᵤₜ(Pₛ, Pₙ)≦P, and solving for Pₛ. For a given τₙ, the lower bound on Pₛ is dominated by the transmission delay constraint D, by letting τ(Pₛ,Pₙ,τₙ)≦D.

The derivation of the bounds indicates that a stringent outage probability constraint leads to a smaller upper bound of Pₛ with the increase of Pₙ, and a stricter D increases the lower bound of Pₛ. As a result, a smaller Pₙ is allowed to satisfy the above two constraints.

Numerical results are given here to provide the reader with a worked example of this. With reference to the PA module design and simulations, and to facilitate the analysis, the efficiency of each of the narrowband PAs is set to 72%, and that of the wideband PA is set to 47.5% including RF switch loss. The turn-on excess delay τₙ of the narrowband PAs is expressed as τₙ=βT, where β depends on the design parameters of the PAs. The delay threshold is defined as D=λT, where λ∈[0,1]. The impacts of β on determining the Pₙ and Pₛ in optimizing the energy efficiency will be discussed as follows.

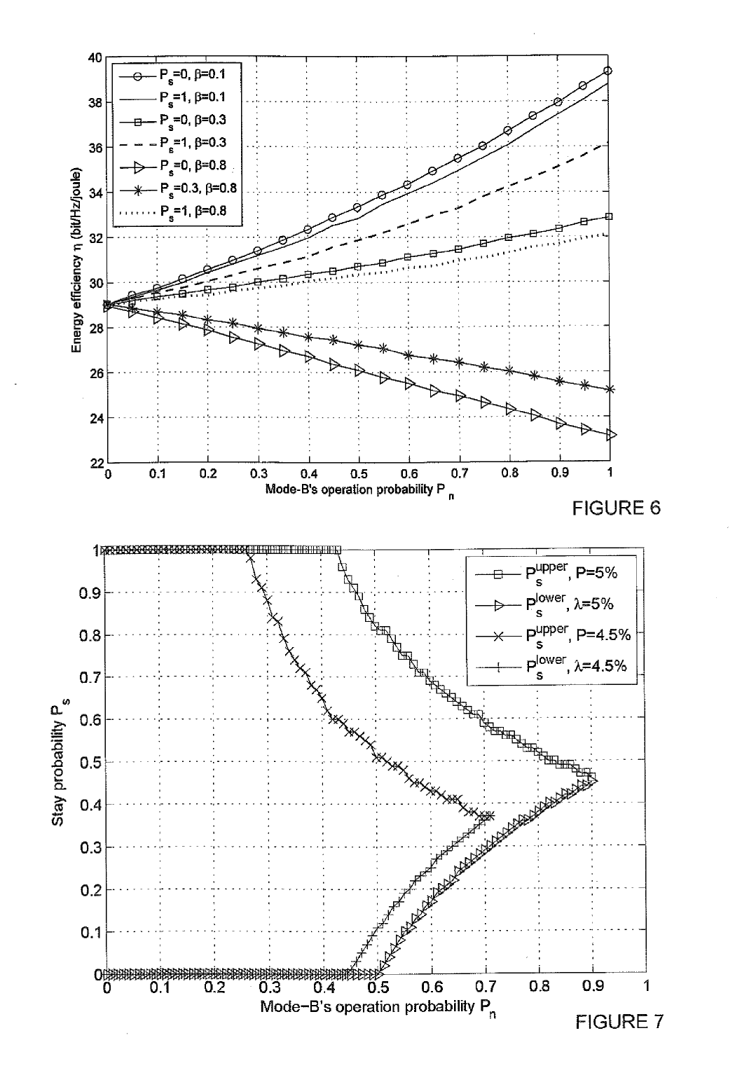

FIG. 6 plots the energy efficiency, η, of the relay 26 as a function of Pₙ, the operation probability of Mode B, for different turn-on delays under different stay probabilities Pₛ. The reader will note that the transmission constraints are not applied for this figure. Using a smaller τₙ (i.e., β=0.1), a higher η can be achieved with the increase of Pₙ. Better efficiency is also achieved for smaller Pₛ. This shows that employment of Mode B (using the narrowband PAs) is desirable, in order to improve energy efficiency. Further, the antenna offering the best performance will always be selected in this case if the transmission constraints can be satisfied.

Using the same Pₙ, η decreases with increasing β. This is because a larger PA turn-on delay results in a higher extra energy consumption, so that η falls. Also, when τₙ is increased, it is desirable to set a higher Pₛ, in order to avoid unnecessary antenna switching and the associated turn-on delay, to maintain acceptable values for η. Furthermore, it can be observed from FIG. 6 that, for small values of Pₛ, the relay 26 will employ wideband PA in order to maximise η. This is especially true if a stringent outage probability constraint is given and the narrowband PAs have high τₙ due to hardware characteristics.

FIG. 7 shows the Pₛ bounds of Mode B as a function of Pₙ. Using the same Pₙ, the lower bound of Pₛ increases when a more stringent delay constraint (for example, λ=4.5%) is applied. This indicates that, for a stringent delay constraint, it is beneficial to continue using the current antenna, to avoid delay from antenna selection and the corresponding PA switch. However, the value of Pₛ is upper bounded by the outage probability constraint P. The figure shows that a stringent P (for example P=4.5%) reduces the upper bound of Pₛ. This is because such a stringent outage probability constraint requires the relay 26 to switch between antennas more often, in order to exploit the multiple-channel diversity so that a satisfactory transmission reliability can be achieved. It is worth noting that, when applying Mode A only (Pₙ=0) during the packet transmission, Pₛ is not actually applicable because the best antenna will always be selected. The latter is powered by a single wideband PA with no extra PA switch delay and energy consumption.

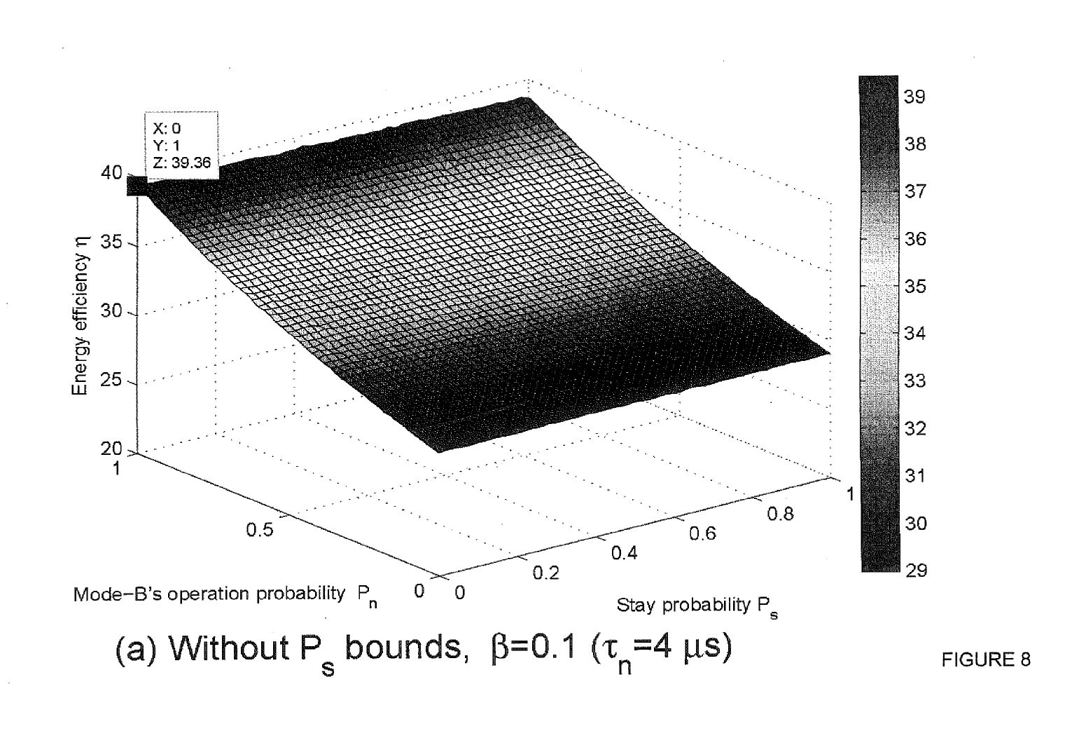

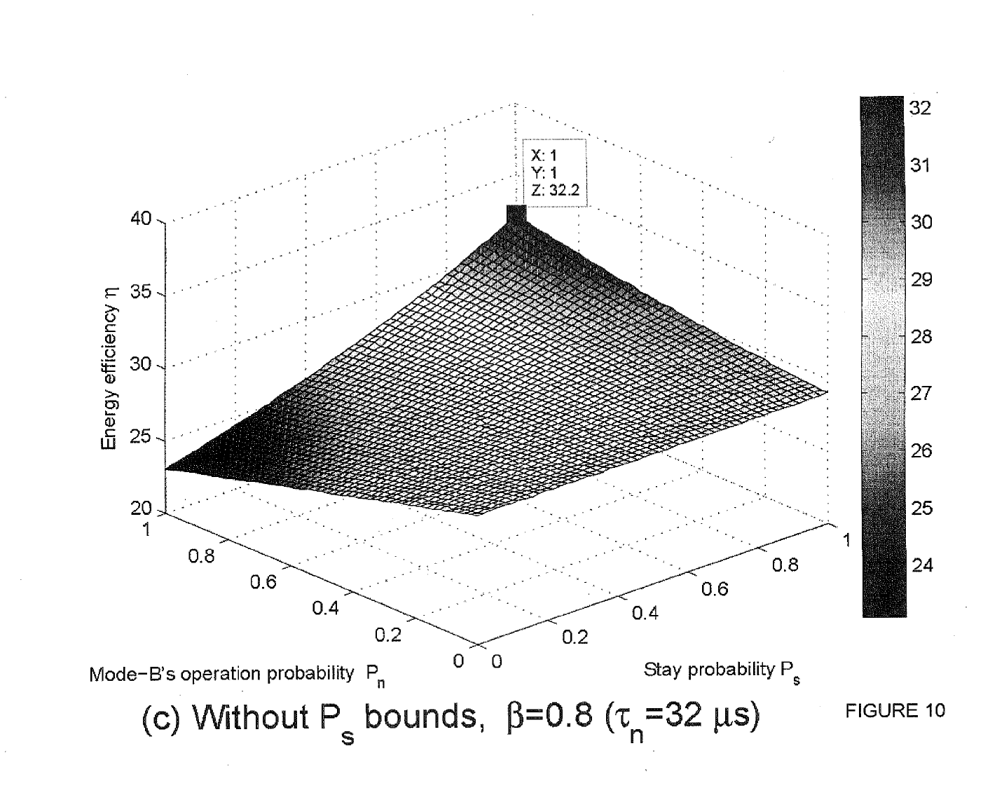

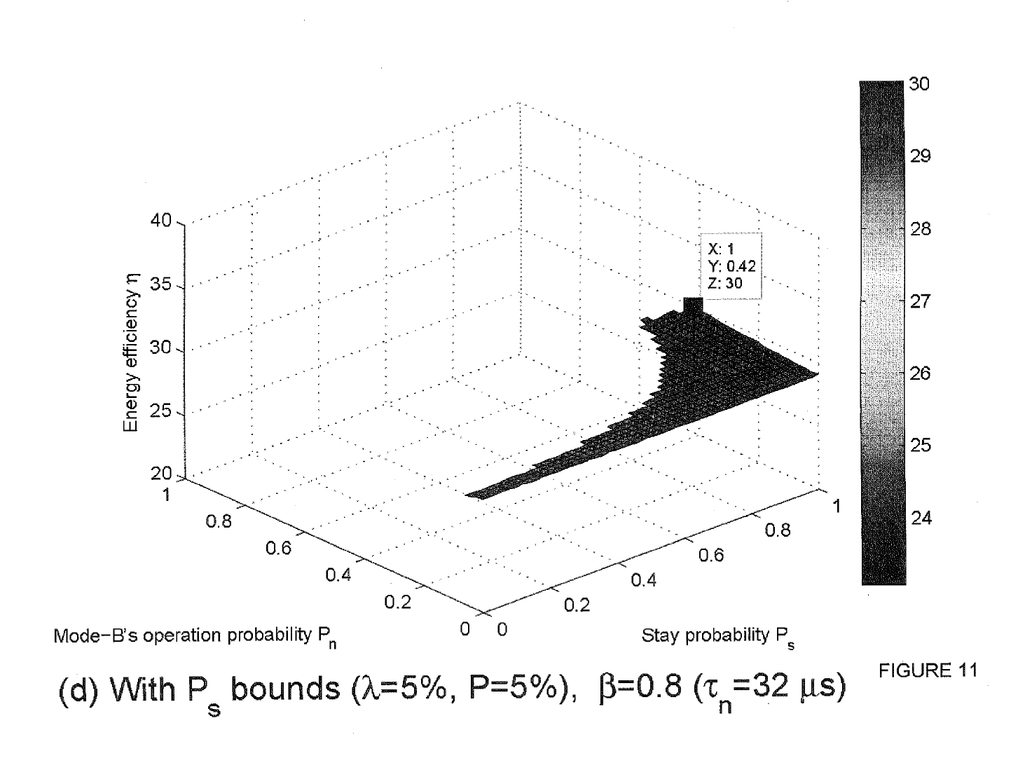

FIGS. 8 to 11 show the energy efficiency, η, as a joint function of Pₛ and Pₙ with respect to PA turn-on delay, τₙ, with and without constraints. It will be observed from FIG. 8 and FIG. 10 that, without considering the transmission constraints, Mode B (Pₙ=1 with narrowband PAs) will always be chosen regardless of the value of τₙ.

However, the choice of Pₛ depends on the value of τⁿ. In particular, it is most energy-efficient to switch to the antenna with a higher channel gain at all times (Pₛ=0) if a smaller τₙ=4 μs (β=0.1) is given by the narrowband PAs. On the other hand, if τₙ becomes significant compared to the length of T (e.g., β=0.8), then it is recommended to set Pₛ=1 in order to ensure that the driver remains on the current antenna for the highest energy efficiency.

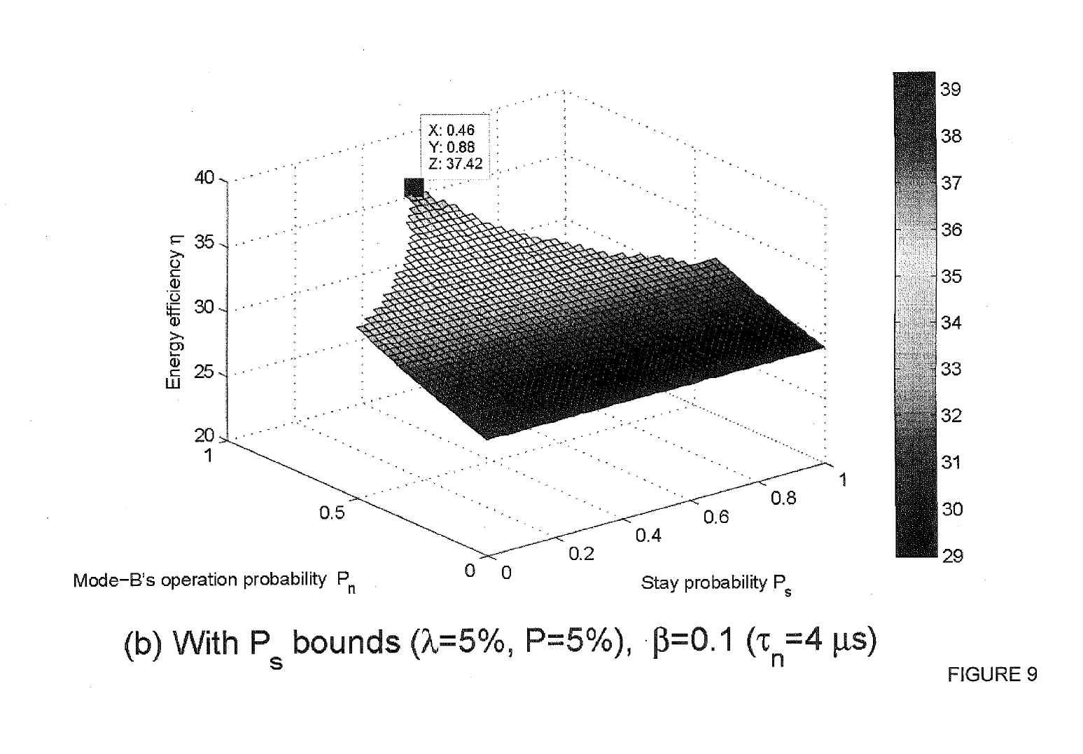

The impact of the transmission constraints on the energy efficiency is shown in FIGS. 9 and 11. These graphs confirm the previous analysis that the upper and lower bounds of Pₛ are determined by the target outage probability and delay constraints. Energy efficiency will decrease by introducing these constraints. As an example from these figures, η decreases from 39.36 bit Hz⁻¹J⁻¹ to 37.42 bit Hz⁻¹J⁻¹ for a small turn-on delay (e.g., β=0.1), and it drops from 32.2 bit Hz⁻¹J⁻¹ to 30 bit Hz⁻¹J⁻¹ when β=0.8. Note that the changes of η may vary, depending on the stringency of the constraints introduced by the system.

Aiming to provide an energy-efficient relaying system in wireless body healthcare network, embodiments described herein provide a mode-switch power amplifier set for a relay node, facilitated by a PA switch/stay operation mechanism taking into account transmission reliability constraints. Antenna selection is applied in the relay node to improve such transmission reliability.

The proposed architecture and switch/stay mechanism can also be applied in different scenarios, such as in a relaying/base station for cellular networks; cognitive/smart networks or in other heterogeneous networks.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes may be made without departing from the spirit of the inventions. The accompanying claims and their equivalents are intended to cover such forms or modifications as would fall within the scope and spirit of the inventions.

1. A multi-mode power amplifier device comprising
a signal input and first and second antenna outputs, each antenna output being suitable for connection to a corresponding antenna;
a wideband power amplifier operable to amplify an input signal applied to an input thereof and to apply the amplified input signal to one of the antenna outputs; and
a narrowband amplifier unit comprising a first narrowband amplifier and a second narrowband amplifier, wherein:
the first narrowband power amplifier is operable to amplify An input signal applied to an input thereof with respect to a first centre frequency and to apply the amplified input signal to the first antenna output; and
the second narrowband power amplifier is operable to amplify an input signal applied to an input thereof with respect to a second centre frequency, different from the first centre frequency, and to apply the amplified input signal to the second antenna output;
the amplifier device being operable in two modes, wherein:
in a first mode a signal applied at the signal input is presented to the wideband power amplifier for amplification thereof, and
in a second mode a signal applied at the signal input is presented to the narrowband amplifier unit;
the amplifier device being operable in two antenna selection states, wherein:
in the first mode, the antenna selection state determines the antenna output to which the amplified input signal is applied; and
in the second mode, the antenna selection state determines to which of the first and second narrowband power amplifiers the signal applied at the signal input is applied and thus to which of the antenna outputs the amplified input signal is applied.

2. An amplifier device in accordance with claim 1 and further comprising a controller, the controller being operable to select one of the two modes and one of the two antenna selection states.

3. An amplifier device in accordance with claim 2 wherein the controller is operable to receive channel information concerning channels of communication associated with each of the wideband amplifier and the first and second narrowband amplifiers.

4. An amplifier device in accordance with claim 3 wherein the controller is operable to process the received channel information and to base its selection of modes and antenna selection states on that processed information.

5. An amplifier device in accordance with claim 4 wherein the controller is operable to determine a switching condition, the switching condition expressing a tendency for the mode and/or antenna selection state for transmission of a particular finite duration signal to be different from the mode and/or antenna selection state for a preceding finite duration signal amplified by the amplifier device, the switching condition being determined dependent on received channel information.

6. An amplifier device in accordance with claim 5 wherein the switching condition comprises an antenna selection state switching condition, the switching condition expressing a tendency for the antenna selection state, for a particular finite duration signal applied at the signal input, to be the same as for a preceding finite duration signal applied at the signal input, regardless of channel condition in the unutilised antenna selection state.

7. An amplifier device in accordance with claim 5 wherein the switching condition comprises a mode switching condition, the mode switching condition governing, on the basis of received channel information, whether the mode of the amplifier device for a particular finite duration signal applied at the signal input should be the same as for a preceding finite duration signal applied at the signal input, regardless of channel condition in the other mode.

8. A controller for controlling a multi-mode amplifier device, the multi-mode amplifier device being operable in one of two modes selectable by a mode control signal provided by the controller, the two modes being a wideband mode and a narrowband mode, and in one of two output selection states, each output selection state being associated with a respective one of two outputs, the output selection state being selectable by an output selection state control signal, the controller being operable to determine a mode control signal and an output selection state for a finite operating period on the basis of preceding states of said signals for a preceding operating period and on the basis of conditions of channels defined by combinations of output and mode, such that a decision to change from at least one of the preceding states is based on an optimisation of efficiency of the wideband mode of the amplifier device as opposed to efficiency, turn-on delay and energy consumption associated with the narrowband mode of the amplifier device.

9. A controller in accordance with claim 8 wherein the controller is operable to perform an optimisation to determine said decision, on the basis of a predetermined probability that switching mode will improve efficiency of said amplifier device.

10. A controller in accordance with claim 8, wherein the controller is operable to perform an optimisation to determine said decision, on the basis of a predetermined probability that, in the event that said mode is said narrowband mode, switching output state will improve efficiency of said amplifier device.
